(19) United States
(12) Patent Application Publication
(10) Pub. No.: US 2010/0015788 A1
(43) Pub. Date: Jan. 21, 2010

(54) METHOD FOR MANUFACTURING SEMICONDUCTOR DEVICE

(76) Inventors: Yuichiro Sasaki, Osaka (JP); Katsumi Okashita, Osaka (JP); Bunji Mizuno, Osaka (JP)

Correspondence Address: MCDERMOTT WILL & EMERY LLP, 600 13TH STREET, NW, WASHINGTON, DC, 20005-3096, US

(21) Appl. No.: 12/518,392

(22) PCT Filed: Sep. 5, 2008
(86) PCT No.: PCT/JP2008/002458

§ 371 Date: Jun. 9, 2009

(30) Foreign Application Priority Data
Sep. 10, 2007 (JP) 2007-234739

(51) Int. Cl. H01L 21/265

(52) U.S. Cl. 438/513; 257/E21.334

(57) ABSTRACT

Plasma doping is performed by exposing a support substrate 11 made of a semiconductor to a plasma generated from a mixed gas of boron 51 which is an impurity and hydrogen 52 and helium 53 which are diluents so as to implant the boron 51 into the support substrate 11. Then, a preliminary heating step is performed by heating the support substrate 11 so that doses of the hydrogen 52 and the helium 53 are smaller than that of the boron 51 in the support substrate 11 by utilizing a difference between a thermal diffusion coefficient of the boron 51 in the support substrate 11 and those of the hydrogen 52 and the helium 53. Then, a laser heating step is performed for electrically activating the boron 51 implanted into the support substrate 11 using a laser.

### TECHNICAL FIELD

The present invention relates to a method for manufacturing a semiconductor device and, more particularly, to a heat treatment method for activating the impurity implanted by plasma doping.

### BACKGROUND ART

In recent years, there are increasing demands for miniaturizing semiconductor devices along with the increase in the degree of integration, functionality and speed thereof. Particularly, it is important to form a thin impurity region, and attention has been drawn to the method for activating an implanted impurity as well as to the method for shallowly implanting an impurity. In order to form a thin impurity region, it is preferred that the activation heat treatment after the impurity introduction is performed for a very short period of time at a high temperature. In the prior art, spike RTA (rapid thermal annealing) has been used for the activation heat treatment after the impurity introduction, and it is currently used in the manufacture of many semiconductor devices. However, an activation heat treatment using spike RTA has a problem in that it has substantial impurity diffusion, whereby the impurity region is formed to be deep.

LSA (Laser Spike Anneal) for activating an impurity by irradiating a substrate into which an impurity has been introduced with laser for a short period of time has been drawing public attention as an activation heat treatment method capable of suppressing the diffusion of an impurity. However, LSA has a problem in that the laser controllability is poor, and variations in the laser output power increase variations in the impurity activation rate, thus resulting in variations in the characteristics of the semiconductor device.

As a countermeasure, a method has been proposed in the art in which an impurity activation heat treatment is performed using LSA after performing spike RTA under conditions in which the heat load is reduced (S. Severi, et al., Optimization of Sub-Melt Laser Anneal: Performance and Reliability, IEDM Tech. Dig., p. 859, 2006: hereinafter referred to as “Non-Patent Document 1”). This method first performs spike RTA to activate a portion of the introduced impurity, and then performs LSA. In this way, it is possible to form a shallow impurity region while sufficiently activating the introduced impurity. Even with this method, however, most of the introduced impurity is activated by LSA, and variations in the laser output power increase variations in the impurity activation, thus failing to overcome the problem of sensitive variations in the characteristics of the impurity region.

In view of this, in order to solve the problem above, an impurity activation method has been proposed in the art in which LSA is first performed, and then spike RTA is performed (T. Yamamoto, et al., Advantages of a New Scheme of Junction Profile Engineering with Laser Spike Annealing and Its Integration into a 45-nm Node High Performance CMOS Technology, 2007 Symposium on VLSI Technology Digest of Technical Papers, p. 122: hereinafter referred to as “Non-Patent Document 2”). Specifically, Non-Patent Document 2 discloses a method for electrically activating an impurity by a procedure including implanting an impurity such as boron, arsenic or phosphorus into a silicon substrate using ion implantation, performing LSA, and then performing spike RTA. According to this method, it is possible to improve the non-uniformity of impurity activation rate due to variations in the laser output power, and to obtain intended impurity region characteristics. Therefore, activation heat treatment methods in which spike RTA is performed after LSA have been expected as promising methods for manufacturing a semiconductor device with a wide process window.

### DISCLOSURE OF THE INVENTION

### Problems To Be Solved By The Invention

However, as the miniaturization develops in the future, it will be necessary to form an impurity region that is thinner and has a lower resistance than an impurity region obtained by the method of Non-Patent Document 2.

In view of the above, it is an object of the present invention to realize an impurity region that is thinner and has a lower resistance.

### Means For Solving The Problems

In order to achieve the object set forth above, a method for manufacturing a semiconductor device of the present invention includes: a plasma doping step of exposing a semiconductor to a plasma generated from a mixed gas of an impurity and a diluent so as to implant the impurity into the semiconductor; and a laser heating step of electrically activating the impurity implanted into the semiconductor using a laser, the method further including a preliminary heating step, after the plasma doping step and before the laser heating step, of heating the semiconductor so that a dose of the diluent in the semiconductor is smaller than that of the impurity by utilizing a difference between a thermal diffusion coefficient of the impurity in the semiconductor and that of the diluent.

According to the method for manufacturing a semiconductor device of the present invention, preliminary heating for discharging a diluent contained in the plasma-generating gas out of the semiconductor is performed before the laser heating for activating the impurity. Therefore, it is possible to prevent the diluent from being rapidly eliminated from the semiconductor during laser heating, i.e., millisecond-order rapid heating, forming irregularities of about some 10 nm on the semiconductor surface. Since plasma doping is used for the impurity implantation, the impurity implantation depth can be made shallower as compared with a case where an ion implantation is used. Moreover, by making the semiconductor surface, i.e., the impurity implantation layer, amorphous by plasma doping, it is possible to electrically activate the impurity by laser heating while keeping a high optical absorption rate of the impurity implantation layer. Thus, it is possible to efficiently activate the introduced impurity while suppressing the undesirable diffusion of the impurity.

Therefore, according to the method for manufacturing a semiconductor device of the present invention, it is possible to form an impurity region with a smaller thickness and a smaller resistance by combining together plasma doping and laser heating, while preventing, by preliminary heating, the deterioration in the characteristics of the semiconductor device due to irregularities on the semiconductor surface. That is, it is possible to realize a semiconductor device having a flat semiconductor surface and an ultra-shallow junction.

In the method for manufacturing a semiconductor device of the present invention, it is preferred that the preliminary heating step is performed with a temperature and a time such that the impurity does not substantially diffuse in the semiconductor; and/or that the plasma doping step includes a step of forming an amorphous layer on a surface of the semiconductor, and the preliminary heating step is performed with a temperature and a time such that the amorphous layer remains.

That is, it is preferred that the preliminary heating step of the present invention is performed with a temperature and a time such that only the diluent such as helium or hydrogen (the diluent of the plasma-generating gas) can be removed from the semiconductor without substantially diffusing the impurity such as boron, phosphorus or arsenic and without causing crystalline recovery in most of the amorphous layer formed by the plasma doping. Then, even if millisecond-order rapid heating such as LSA, for example (specifically, heating at a temperature of 900° C. or more for 10 milliseconds or less) is performed as the laser heating, it is possible to reliably prevent irregularities from being formed on the semiconductor surface such as a silicon substrate, for example. It is possible to reliably realize effects described above if the preliminary heating step of the present invention is performed at a temperature of 300° C. or less (a temperature of 50° C. or more, which is sufficiently higher than room temperature).

It is preferred that the method for manufacturing a semiconductor device of the present invention further includes another heating step of heating the semiconductor after the laser heating step, specifically, a step of heating the semiconductor using spike RTA at a temperature of 800° C. or more for 30 seconds or less. Then, it is possible to activate an impurity that has not been electrically activated during the laser heating, and it is therefore possible to stably manufacture desirable semiconductor devices, irrespective of variations in the laser output power. Although crystalline recovery occurs in most of the amorphous layer formed by the plasma doping due to millisecond-order laser heating such as LSA, for example, crystalline recovery may not occur in a portion having a thickness of about some nm upon completion of the laser heating. In this case, it is possible to cause a complete crystalline recovery of the semiconductor by additionally performing spike RTA following the laser heating.

In the method for manufacturing a semiconductor device of the present invention, the impurity introduced into the semiconductor may be, for example, boron, arsenic, phosphorus, or the like.

In the method for manufacturing a semiconductor device of the present invention, the diluent contained in the material gas for generating a plasma used in the plasma doping is hydrogen or a rare gas, for example, and helium is most preferred among other rare gases.

### EFFECTS OF THE INVENTION

According to the present invention, an impurity can be sufficiently activated while suppressing the diffusion of an impurity introduced by plasma doping, and it is therefore possible to form an impurity region having a low sheet resistance and having an ultra-shallow junction. By combining together plasma doping and laser heating, it is possible to prevent irregularities from being formed on the surface of the semiconductor where an impurity region is formed. In other words, it is possible to keep the semiconductor surface flat. With these superior properties, the present invention can ensure miniaturization of semiconductor devices.

### BRIEF DESCRIPTION OF THE DRAWINGS

FIGS. 1(a)-1(e) are cross-sectional views showing steps of a method for manufacturing a semiconductor device according to one embodiment of the present invention, and FIGS. 1(f)-1(e) show, on an enlarged scale, a portion of an extension formation region (including a source/drain formation region) shown in FIGS. 1(a)-1(e) up to a depth of 100 nm from the substrate surface.

FIG. 2 shows the heating time and the heating temperature with which B, As or P as an impurity diffuses over 1 nm in silicon.

FIG. 3 shows diffusion coefficients of various elements, including boron (B), phosphorus (P) and arsenic (As) which are impurities, and hydrogen (H) and helium (He) which are diluents.

FIG. 4(a) shows the hydrogen concentration in the silicon substrate (semiconductor) immediately after plasma doping (PD), in comparison with that after preliminary heating following the plasma doping, and FIG. 4(b) shows the helium concentration in the silicon substrate (semiconductor) immediately after plasma doping (PD), in comparison with that after preliminary heating following the plasma doping.

FIG. 5 shows, in a tabular format, the dose of the impurity (boron) and that of the diluent (hydrogen and helium) before and after the preliminary heating following the plasma doping.

FIG. 6 shows a cross-sectional TEM image of a silicon substrate surface portion obtained by a method for manufacturing a semiconductor device according to one embodiment of the present invention.

FIG. 7 shows the implantation dose (concentration) of an impurity (boron) after plasma doping is performed on a silicon substrate using B₂H₆ diluted with He as the material gas.

FIG. 8 shows the implantation dose (concentration) of hydrogen after plasma doping is performed on a silicon substrate using B₂H₆ diluted with He as the material gas.

FIG. 9 shows the implantation dose (concentration) of helium after plasma doping is performed on a silicon substrate using B₂H₆ diluted with He as the material gas.

FIG. 10(a) is a schematic cross-sectional view of a silicon substrate surface portion (impurity implantation layer) containing a large amount of a diluent (e.g., helium or hydrogen) when an impurity (boron) is introduced using plasma doping, and FIG. 10(b) is a schematic cross-sectional view showing hydrogen and helium, which are diluents, evaporating as if they were boiling by millisecond-order rapid heating using laser heating, thereby forming irregularities on the silicon substrate surface.

FIGS. 11(a)-11(d) are cross-sectional views showing steps of a method for manufacturing a semiconductor device according to a first comparative example, and FIGS. 11(e)-11(h) show, on an enlarged scale, a portion of an extension formation region (including a source/drain formation region) shown in FIGS. 11(a)-11(d) up to a depth of 100 nm from the substrate surface.

FIG. 12 is a cross-sectional TEM image of a silicon substrate surface portion obtained when an impurity is electrically activated by laser heating without performing preliminary heating following plasma doping in the first comparative example.

FIG. 13(a) shows an example of a cross-sectional structure of a MOSFET, and FIGS. 13(b) and 13(c) are cross-sectional views schematically showing the OFF state and the ON state, respectively, of a MOSFET with a shortened gate length.

FIG. 14(a) is a cross-sectional view schematically showing the ON state of a MOSFET in which there is a recess near the gate electrode, and FIG. 14(b) is a cross-sectional view schematically showing the ON state of a MOSFET in which there is a recess at a position away from the gate electrode.

FIGS. 15(a)-15(d) are cross-sectional views showing steps of a method for manufacturing a semiconductor device according to a second comparative example, and FIGS. 15(e)-15(h) show, on an enlarged scale, a portion of an extension formation region (including a source/drain formation region) shown in FIGS. 15(a)-15(d) up to a depth of 100 nm from the substrate surface.

FIG. 16(a) shows the optical absorption coefficients of amorphous silicon crystal (a-Si) and crystalline silicon (c-Si) with respect to the wavelength of light, and FIG. 16(b) shows the ratio of the optical absorption coefficient of a-Si with respect to that of c-Si.

### DESCRIPTION OF REFERENCE NUMERALS

11 Support substrate
12 Active region
13 Impurity implantation layer
14 Amorphous layer
15 Impurity diffusion layer
51 Boron
52 Hydrogen
53 Helium

### BEST MODE FOR CARRYING OUT THE INVENTION

### Embodiment

Now, a method for manufacturing a semiconductor device according to one embodiment of the present invention will be described with reference to the drawings.

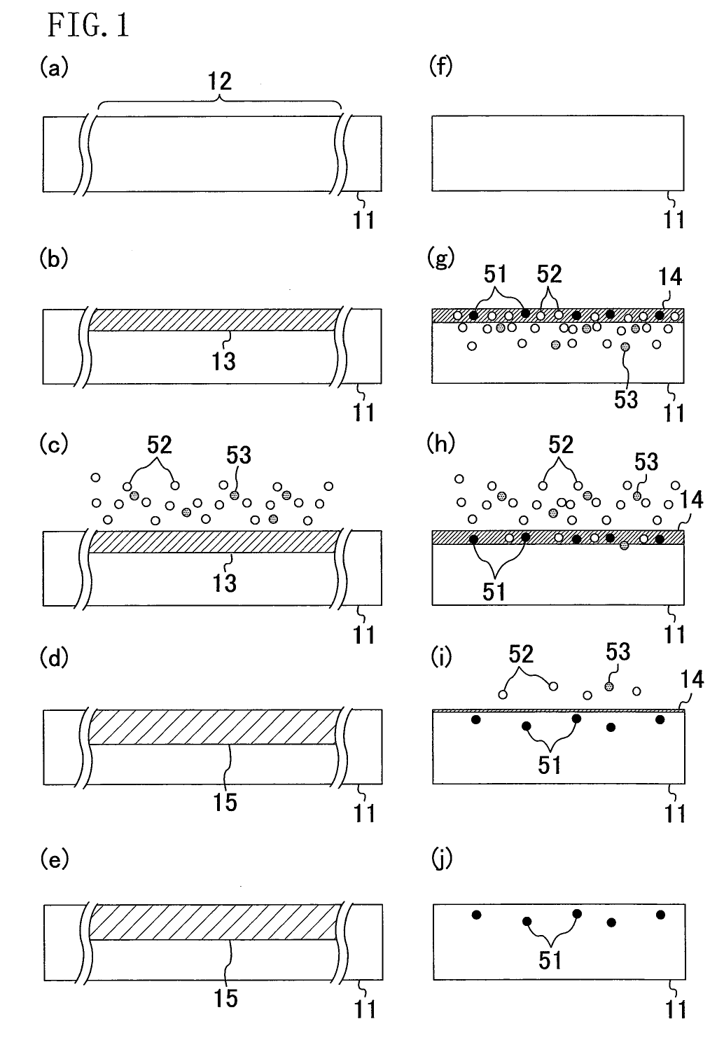

FIGS. 1(a)-1(e) are cross-sectional views showing steps of a method for manufacturing a semiconductor device according to the present embodiment, and FIGS. 1(f)-1(j) show, on an enlarged scale, a portion of an extension formation region (including a source/drain formation region) shown in FIGS. 1(a)-1(e) up to a depth of 100 nm from the substrate surface.

First, as shown in FIGS. 1(a) and 1(f), there is provided a support substrate 11 made of silicon, for example, and having a thickness of 800 μm. Then, an isolation trench (not shown) is formed by patterning in the support substrate 11, thereby forming an active region 12 where a source/drain region and an extension region of an N-type MISFET (metal-insulator-semiconductor field-effect transistor), for example, are formed.

Then, as shown in FIGS. 1(b) and 1(g), plasma doping is performed on an extension formation region in the support substrate 11 for doping with a p-type impurity, for example, thus forming an impurity implantation layer 13. Herein, the plasma doping conditions are such that, for example, the material gas is B₂H₆ (diborane) diluted with He (helium), the B₂H₆ concentration in the material gas is 1.0% by mass, the total flow rate of the material gas is 200 cm³/min (standard state), the chamber pressure is 1.0 Pa, the source power (plasma-generating high-frequency power) is 1000 W, the bias voltage (Vpp) is 300 V, the substrate temperature is 20° C., and the plasma doping time is 60 seconds. In this process, at the same time as boron 51 which is an impurity is implanted into the support substrate 11, hydrogen 52 and helium 53 which are diluents are also implanted into the support substrate 11. At the same time with the impurity implantation, an amorphous layer 14 is formed on the surface of the support substrate 11. In the present embodiment, plasma doping conditions are adjusted so that the amorphous layer 14 is formed inside the impurity implantation layer 13 (a region where the concentration of the boron 51 is, for example, 5×10¹⁸ cm⁻³ or more).

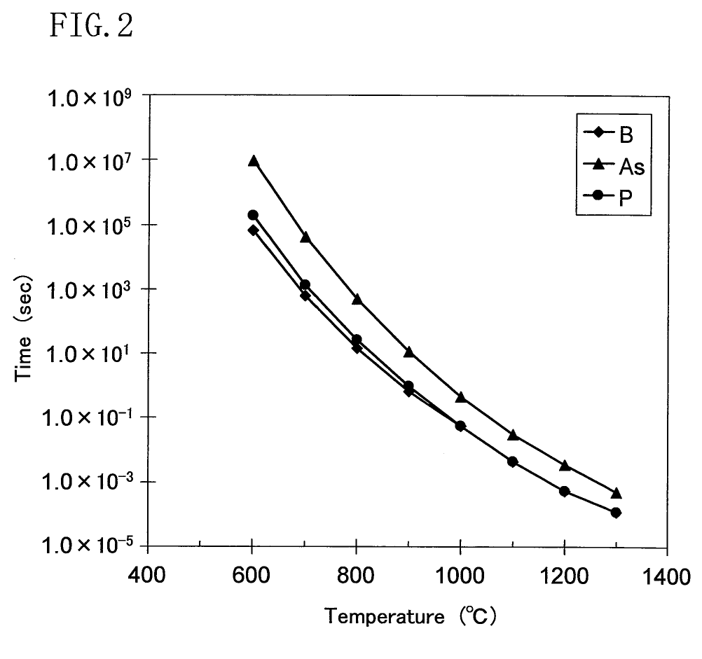

Then, as shown in FIGS. 1(c) and 1(h), utilizing the difference between the thermal diffusion coefficient of the boron 51 which is an impurity in the support substrate 11 and those of the hydrogen 52 and the helium 53 which are diluents, a heating operation (hereinafter referred to as “preliminary heating”) is performed on the support substrate 11 so that the total dose of the hydrogen 52 and the helium 53 which are diluents in the support substrate 11 (i.e., the impurity implantation layer 13) is smaller than that of the boron 51 which is an impurity. As the preliminary heating conditions, the time and the temperature are selected so that the boron 51 does not substantially diffuse in the support substrate 11, and the hydrogen 52 and the helium 53 slowly come out of the support substrate 11. In the present specification, “to not substantially diffuse” means that “the diffusion length is 1 nm or less”. FIG. 2 shows the heating time and the heating temperature with which B, As or P as an impurity diffuses over 1 nm in silicon. That is, heating conditions on the left side of the graph of each impurity in FIG. 2 represent “the heating conditions with which the impurity does not substantially diffuse”. In the present embodiment, the preliminary heating conditions are adjusted so that crystalline recovery does not occur in the amorphous layer 14 generated by plasma doping, in other words, so that the amorphous layer 14 remains. Specifically, it is preferred that the heating temperature is 300° C. or less where the amorphous layer 14 is made of silicon as in the present embodiment. Note however that it is preferred that the heating temperature is set to 50° C. or more, which is sufficiently higher than room temperature, in order to remove the hydrogen 52 and the helium 53 from the support substrate 11 while suppressing a decrease in the throughput due to an increase in the heating time.

Then, as shown in FIGS. 1(d) and 1(i), laser heating, e.g., millisecond-order rapid heating operation such as LSA, is performed on the impurity implantation layer 13 to thereby electrically activate the impurity (the boron 51) of the impurity implantation layer 13, thus forming an impurity diffusion layer 15 to be an extension region, for example. In this process, in the millisecond-order rapid heating (specifically, heating for 10 milliseconds or less at a temperature of 900° C. or more), the laser light can be made to be efficiently absorbed by the amorphous layer 14, thereby electrically activating the boron 51. At the same time, the hydrogen 52 and the helium 53 remaining in the support substrate 11 can be eliminated from the support substrate 11. Moreover, after the laser heating, the amorphous layer 14 formed by plasma doping disappears while leaving a portion thereof having a thickness of about some nm. That is, most of the amorphous layer 14 returns to the crystalline state.

Then, as shown in FIGS. 1(e) and 1(j), a further heating operation is performed on the impurity diffusion layer 15. In the present embodiment, the support substrate 11 is heated for 30 seconds or less at a temperature of 800° C. or more using spike RTA, for example. Thus, it is possible to sufficiently electrically activate the impurity (the boron 51) in the impurity diffusion layer 15. In this process, by the laser heating operation shown in FIGS. 1(d) and 1(i), the rest of the amorphous layer 14, for which crystalline recovery has not occurred, can be completely returned to the crystalline state.

A characteristic of the present embodiment is that the impurity implantation layer 13 is formed using plasma doping, and then preliminary heating is performed at a relatively low temperature before electrically activating the boron 51 which is the implanted impurity by laser heating. Thus, by the plasma doping, the diluents (i.e., the hydrogen 52 and the helium 53), which have been implanted into the support substrate 11 at the same time with the impurity (i.e., the boron 51), can be slowly diffused to the outside of the support substrate 11. Thus, it is possible to reduce the hydrogen 52 and the helium 53 remaining in the impurity implantation layer 13 immediately before the start of the laser heating. Therefore, even if the impurity (i.e., the boron 51) is electrically activated by laser heating, which is millisecond-order rapid heating, it is possible to prevent a large amount of diluents (i.e., the hydrogen 52 and the helium 53) from being rapidly eliminated from the support substrate 11 and to thereby prevent the formation of irregularities of about some 10 nm on the surface of the support substrate 11. Thus, it is possible to obtain intended transistor characteristics.

According to the present embodiment, since plasma doping is used for the impurity implantation, the impurity implantation depth can be made shallower than that obtained by ion implantation. Moreover, it is possible to electrically activate the impurity by laser heating while keeping a high optical absorption rate of the impurity implantation layer 13 by making the surface of the support substrate 11, i.e., the impurity implantation layer 13, amorphous by plasma doping. Thus, it is possible to efficiently activate the introduced impurity while suppressing the undesirable diffusion of the impurity (i.e., the boron 51).

Therefore, according to the present embodiment, it is possible to form the impurity diffusion layer 15, which is shallower and has a lower resistance, by combining plasma doping and laser heating together, while preventing, by preliminary heating, the deterioration in the characteristics of the semiconductor device due to irregularities on the surface of the support substrate 11. That is, it is possible to realize a semiconductor device having a flat semiconductor surface and an ultra-shallow junction.

While the formation of a p-type impurity region as an extension region of an N-type MISFET has been described as an example in the present embodiment, it is understood that the present invention can be used for the formation of an n-type impurity region as a source/drain region of an N-type MISFET, the formation of an n-type impurity region as an extension region of a P-type MISFET, and the formation of a p-type impurity region as a source/drain region of a P-type MISFET.

While B₂H₆ diluted with He is used as the material gas of plasma doping in the present embodiment, the material gas is not limited to any particular gas as long as it is a gas containing an impurity to be implanted into an impurity region such as an extension region. For example, instead of B₂H₆, other molecules containing boron atoms (e.g., BF₃), other molecules comprised of boron atoms and hydrogen atoms, or AsH₄, PH₃, etc., may be used. A rare gas other than helium may be used as the diluent gas. Note however that where B₂H₆ diluted with He is used as the material gas of plasma doping as in the present embodiment, it is preferred that the mass concentration of B₂H₆ in the material gas is 0.01% or more and 1% or less. Then, it becomes easier to introduce boron into a semiconductor such as silicon. Conversely, if the B₂H₆ gas concentration is 0.01% or less, it becomes more difficult to introduce a sufficient amount of boron into the semiconductor, and if the B₂H₆ gas concentration is 1% or more, a boron-containing deposit is attached to the surface of the semiconductor, thus producing an undesirable deposition.

Now, the mechanism of the present invention, specifically, the mechanism by which irregularities are prevented from being formed on the semiconductor surface due to rapid elimination of the diluent from the impurity implantation layer, will be described with reference to the drawings.

[Mechanism of the Present Invention]

As described above, if an extension formation region of the support substrate 11 is doped with a p-type impurity by plasma doping, there is formed the impurity implantation layer 13 into which the hydrogen 52 and the helium 53 which are diluents have been implanted together with the boron 51 which is an impurity, and at the same time, the amorphous layer 14 is formed (see FIGS. 1(b) and 1(g)). In this process, in the impurity implantation layer 13, the implantation dose (dose) of the hydrogen 52 and the helium 53 which are diluents is as much as about 4 times that of the boron 51 which is an impurity.

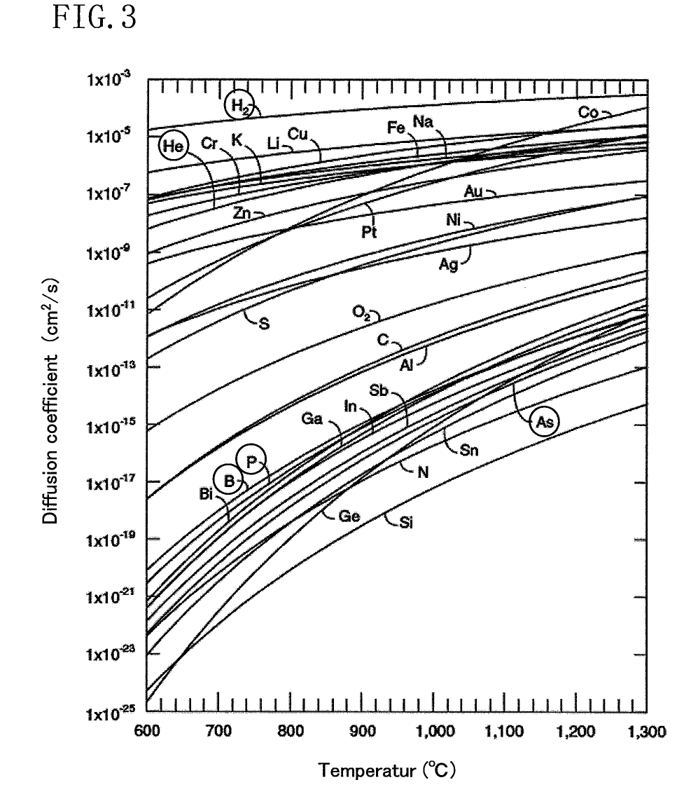

Therefore, if laser heating, i.e., millisecond-order rapid heating, is performed in such a state in order to electrically activate the impurity in the impurity implantation layer 13, i.e., the boron 51, there will be a problem as follows. That is, as shown in FIG. 3, since the diffusion coefficients of hydrogen (H) and helium (He) which are diluents are much greater than those of boron (B), phosphorus (P), arsenic (As), and the like, which are impurities, the hydrogen 52 and the helium 53 evaporate out of the impurity implantation layer 13 as if they were boiling and are eliminated from the support substrate 11. In this process, the hydrogen 52 or the helium 53 is eliminated from the support substrate 11 while pushing away the surrounding silicon, thereby generating irregularities on the surface of the support substrate 11, i.e., on the silicon substrate surface. This phenomenon is particularly pronounced in a case where atoms (e.g., hydrogen, helium, or the like) having a diffusion coefficient much higher than that of the impurity or ions thereof are implanted in large quantities in the impurity implantation layer 13. In contrast, when an impurity implantation layer to be an extension region is formed by ion implantation, or the like, for example, this phenomenon does not occur because an implantation species having a large diffusion coefficient such as hydrogen or helium is not implanted at the same time into the impurity implantation layer.

During the laser heating, a very small portion of boron, phosphorus or arsenic which is the implanted impurity is eliminated from the substrate surface (silicon substrate surface). However, since the heating conditions (the millisecond-order heating time, the heating temperature, etc.) for electrically activating the impurity are set so as to minimize the diffusion of the impurity, only a very small amount of the impurity is eliminated from the silicon substrate surface, which will not generate such irregularities on the silicon substrate surface that the device characteristics are affected.

On the other hand, as described in the present embodiment, if preliminary heating at a relatively low temperature is performed before the laser heating for electrically activating the impurity (the boron 51) of the impurity implantation layer 13, the hydrogen 52 and the helium 53 which are diluents whose diffusion coefficient is an order or orders of magnitude larger than that of the impurity (the boron 51) are slowly eliminated from the surface of the support substrate 11. In this process, since the hydrogen 52 and the helium 53 in the support substrate 11 are eliminated while passing through between silicon particles, irregularities are not generated on the surface of the support substrate 11. Since the impurity implanted in the support substrate 11 has a small diffusion coefficient, the impurity is not eliminated from the surface of the support substrate 11 by preliminary heating at a relatively low temperature. Thus, by performing the preliminary heating, the implantation dose of the hydrogen 52 and the helium 53 which are diluents can be reduced significantly while the boron 51 which is an impurity implanted into the support substrate 11 is kept as it is without being diffused. Therefore, when the laser heating for electrically activating the impurity is performed after the preliminary heating, the hydrogen 52 and the helium 53 remaining in the impurity implantation layer 13 are eliminated, but since there are only slight amounts of the hydrogen 52 and the helium 53 remaining after the preliminary heating, irregularities which may affect the device characteristics are not generated on the surface of the support substrate 11, and it is possible to obtain intended transistor characteristics.

Now, a method in which preliminary heating is performed after plasma doping so as to reduce the implantation dose of hydrogen and helium which are diluents, followed by laser heating for electrically activating the impurity, will be described with respect to a specific example.

### Process Conditions of Example of Present Invention

In one example, an impurity is implanted into a silicon substrate using B₂H₆ (diborane) diluted with He (helium) as the material gas of plasma doping, and then preliminary heating is performed so as to eliminate hydrogen and helium which are diluents from the silicon substrate. Thus, even if laser heating for electrically activating the impurity is performed after the preliminary heating, it is possible to obtain an ultra-thin boron diffusion layer while maintaining the silicon substrate surface flat.

In one example, first, plasma doping is performed on a silicon substrate. The plasma doping conditions are such that the source power is 1000 W, the bias voltage (Vpp) is 300 V, the B₂H₆/He concentration ratio is 1.0% by mass/99.0% by mass, the total flow rate of the material gas is 100 cm³/min (standard state), and the bias application time is 60 seconds. Then, preliminary heating at 300° C., for example, was performed on the silicon substrate for 3 minutes. After the preliminary heating, millisecond-order heating by LSA, for example, was performed as the laser heating.

[Change in Diluent Implantation Dose before and after Preliminary Heating]

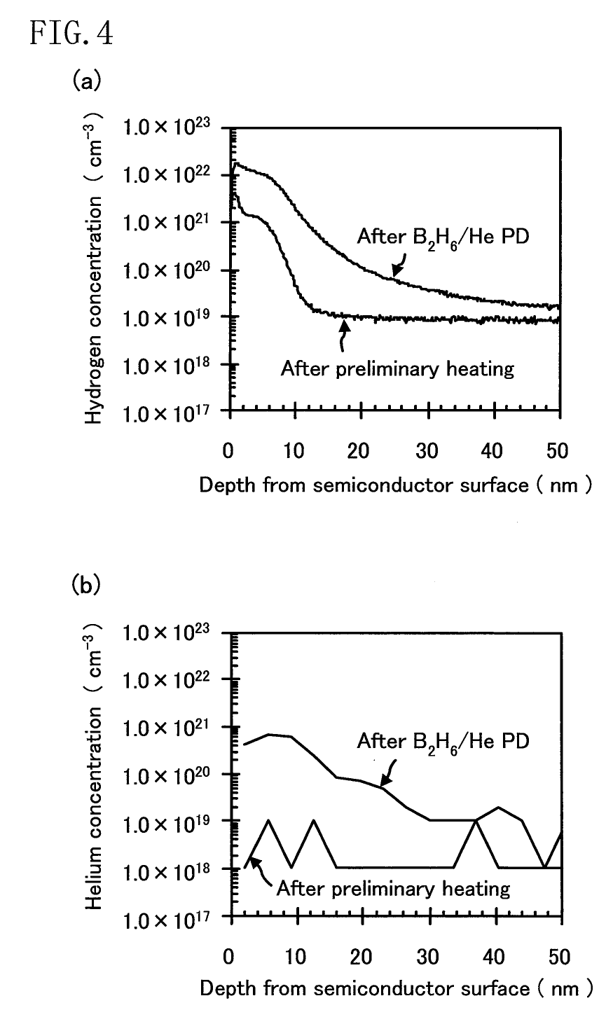

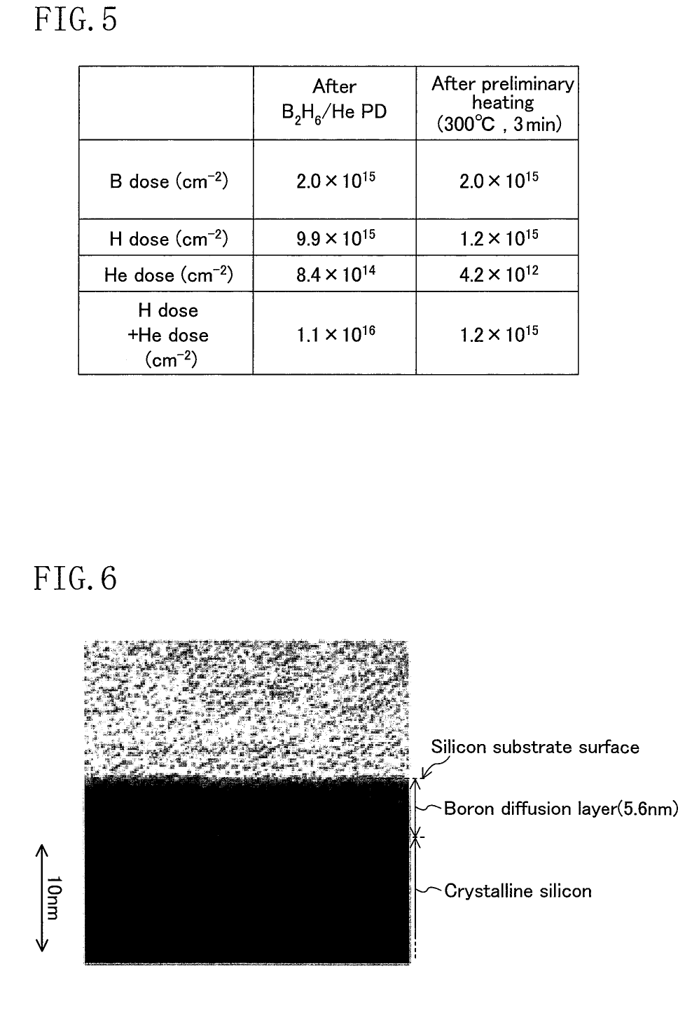

First, the change in the diluent implantation dose before and after the preliminary heating in the present example will be described with reference to FIGS. 4(a), 4(b) and 5. FIG. 4(a) shows the hydrogen concentration in the silicon substrate (semiconductor) immediately after plasma doping (PD), in comparison with that after preliminary heating following the plasma doping. The results shown in FIG. 4(a) indicated that the hydrogen dose after the plasma doping is 9.9×10¹⁵ cm⁻², and that after the preliminary heating is 1.2×10¹⁵ cm⁻². That is, the dose of hydrogen which is a diluent is significantly decreased after the preliminary heating. Similarly, FIG. 4(b) shows the helium concentration in the silicon substrate (semiconductor) immediately after plasma doping (PD), in comparison with that after preliminary heating following the plasma doping. The results shown in FIG. 4(b) indicated that the dose of helium after the plasma doping is 8.4×10¹⁴ cm⁻², and that after the preliminary heating is 4.2×10¹² cm⁻². That is, the dose of helium which is a diluent is significantly decreased after the preliminary heating.

FIG. 5 shows, in an easy-to-understand tabular format, the dose of the impurity (boron) and that of the diluent (hydrogen and helium) before and after the preliminary heating following the plasma doping. As shown in FIG. 5, the total dose of hydrogen and helium which are diluents is 1.1×10¹⁶ cm⁻² after the plasma doping (before the preliminary heating), whereas it is decreased to 1.2×10¹⁵ cm⁻² after the preliminary heating. On the other hand, the dose of boron which is an impurity was 2.0×10¹⁵ cm⁻² after the plasma doping, and was 2.0×10¹⁵ cm⁻² also after the preliminary heating. That is, the boron dose does not change after the preliminary heating.

As described above, according to the present example, while the total dose of hydrogen and helium which are diluents is greater than or equal to five times that of boron which is an impurity after the plasma doping (before the preliminary heating), the total dose of hydrogen and helium which are diluents can be made smaller than that of boron which is an impurity after the preliminary heating.

In order to realize these effects, the heating time should be set to be up to about 3 minutes in a case where the temperature of the preliminary heating is set to 300° C. This is because crystalline recovery occurs in the amorphous layer during the preliminary heating if the heating time is set to be longer than this. Where the temperature of the preliminary heating is set to be smaller than 300° C., the above effects of the present invention can be realized without causing crystalline recovery in the amorphous layer even if the heating time is set to about 3 minutes or more. Specifically, where the temperature of the preliminary heating is set to 250° C., the heating time can be set to be as long as about 20 minutes. Where the temperature of the preliminary heating is set to 50° C., the heating time can be set to be as long as about 10 hours. However, if the temperature of the preliminary heating is set to be lower than 50° C., there will be required a very long period of time for sufficiently diffusing hydrogen and helium to the outside of the support substrate, thus significantly lowering the productivity. That is, if the temperature of the preliminary heating is set to be lower than 50° C., it is not possible to realize effects of the present invention while ensuring the productivity. On the other hand, where the temperature of the preliminary heating is set to be greater than 300° C., it is not possible to realize effects of the present invention without causing crystalline recovery in the amorphous layer unless the heating time is set to be shorter than 3 minutes.

[Irregularities on Silicon Substrate Surface after Laser Heating]

Next, the results obtained by performing laser heating (millisecond-order heating) after the preliminary heating of the present example will be described. In the present example, LSA is used as the laser heating after the preliminary heating. FIG. 6 shows a cross-sectional TEM (Transmission Electron Microscope) image of a silicon substrate surface portion obtained by performing preliminary heating after plasma doping in the present example, followed by millisecond-order heating using LSA. As shown in FIG. 6, in the present example, the silicon substrate surface after the laser heating is flat. The amorphous layer formed by plasma doping has disappeared by crystalline recovery. That is, where the implanted impurity is electrically activated using laser heating after the plasma doping, it is possible to reduce the implantation doses of hydrogen, helium, and the like, which are diluents introduced into the silicon substrate at the same time with the impurity during the plasma doping, by performing preliminary heating after the plasma doping and before the laser heating as in the present example. This is very effective for obtaining an ultra-shallow junction while maintaining a flat silicon substrate surface even after the laser heating, in other words, for obtaining intended semiconductor device characteristics. In the present example, it was possible to obtain an ultra-thin boron diffusion layer having a thickness of 5.6 nm as an impurity diffusion layer, as shown in FIG. 6.

It is preferred that after the implanted impurity is electrically activated using the laser heating as in the present example, a further heating operation, e.g., spike RTA, or the like, is used for electrically activating the impurity. Then, it is possible to reliably obtain an impurity region such as an extension region of a lower sheet resistance and a shallower junction.

### First Comparative Example

A first comparative example is directed to a method for manufacturing a semiconductor device disclosed in Non-Patent Document 2, specifically, a method in which an impurity is implanted into a silicon substrate using an ion implantation, after which an impurity activation heat treatment is performed using LSA without performing preliminary heating, followed by spike RTA, wherein plasma doping is used instead of the ion implantation. In the first comparative example, irregularities of about some 10 nm are formed on the surface of the silicon substrate, thereby unacceptably altering the shape of the semiconductor device. The present inventors researched on the reason therefor, thus obtaining the following findings.

In the plasma doping, a plasma obtained by diluting an impurity with a diluent gas is used, instead of using a plasma comprised solely of the impurity. Moreover, an impurity is often significantly diluted with a diluent gas to 5% by mass or less. Therefore, plasma doping has a characteristic that a larger amount of diluent than the amount of impurity is implanted at the same time with the impurity. A rare gas or hydrogen is used as the diluent gas (diluent), and, among rare gases, helium is used.

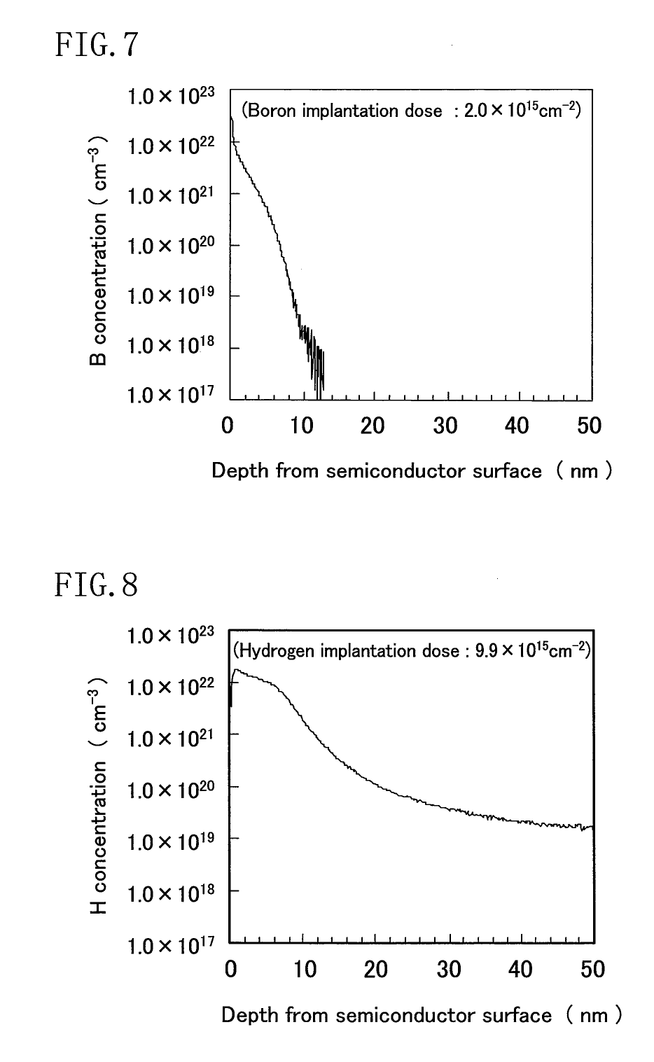

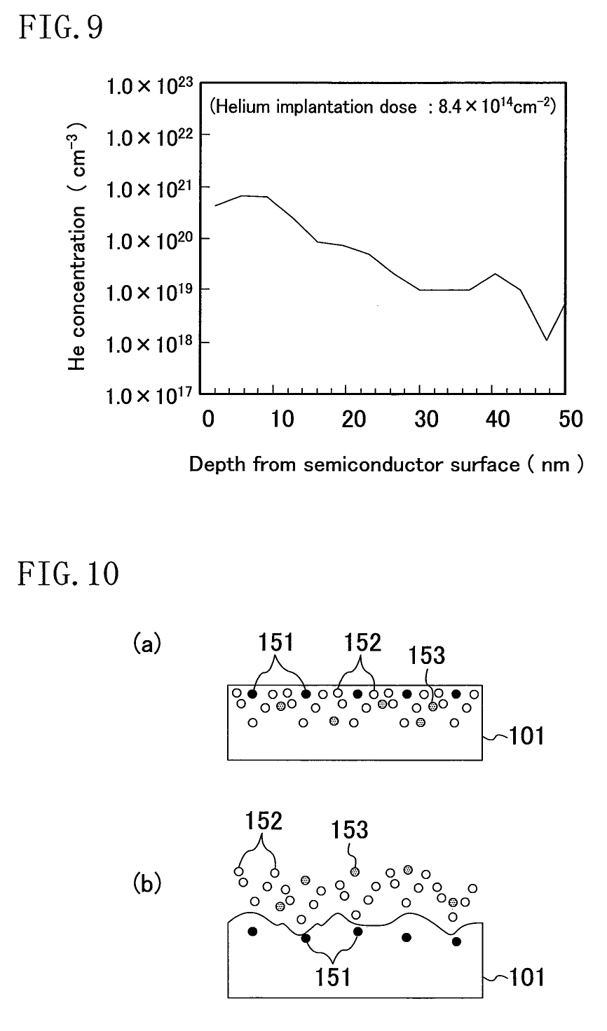

FIGS. 7-9 show the implantation doses (concentration) of an impurity (boron), hydrogen and helium, respectively, after plasma doping is performed on a silicon substrate using B₂H₆ diluted with He as the material gas. As shown in FIGS. 7-9, the implantation dose of helium or hydrogen which is a diluent after the plasma doping is as high as about 5 times that of the implantation dose of the impurity (boron) after the plasma doping.

FIG. 10(a) is a schematic cross-sectional view showing a silicon substrate surface portion (impurity implantation layer) containing a large amount of a diluent (e.g., helium or hydrogen) when an impurity (boron) is introduced using plasma doping. As shown in FIG. 10(a), hydrogen 152 and helium 153 which are diluents are introduced into the surface portion of a silicon substrate 101, together with boron 151 which is an impurity. If millisecond-order rapid heating such as laser heating is performed on an impurity implantation layer containing a large amount of a diluent other than an impurity, the helium 153 and the hydrogen 152 which are diluents having very large diffusion coefficients rapidly come out from the surface of the silicon substrate 101 as if they were boiling. As a result, after the laser heating, irregularities are formed on the surface of the silicon substrate 101. FIG. 10(b) is a schematic cross-sectional view showing the hydrogen 152 and the helium 153, which are diluents, evaporating as if they were boiling by millisecond-order rapid heating using laser heating, thereby forming irregularities on the surface of the silicon substrate 101. If an ion implantation is used as in the method disclosed in Non-Patent Document 2, helium and hydrogen are basically not implanted, and therefore a phenomenon shown in FIG. 10(b) does not occur.

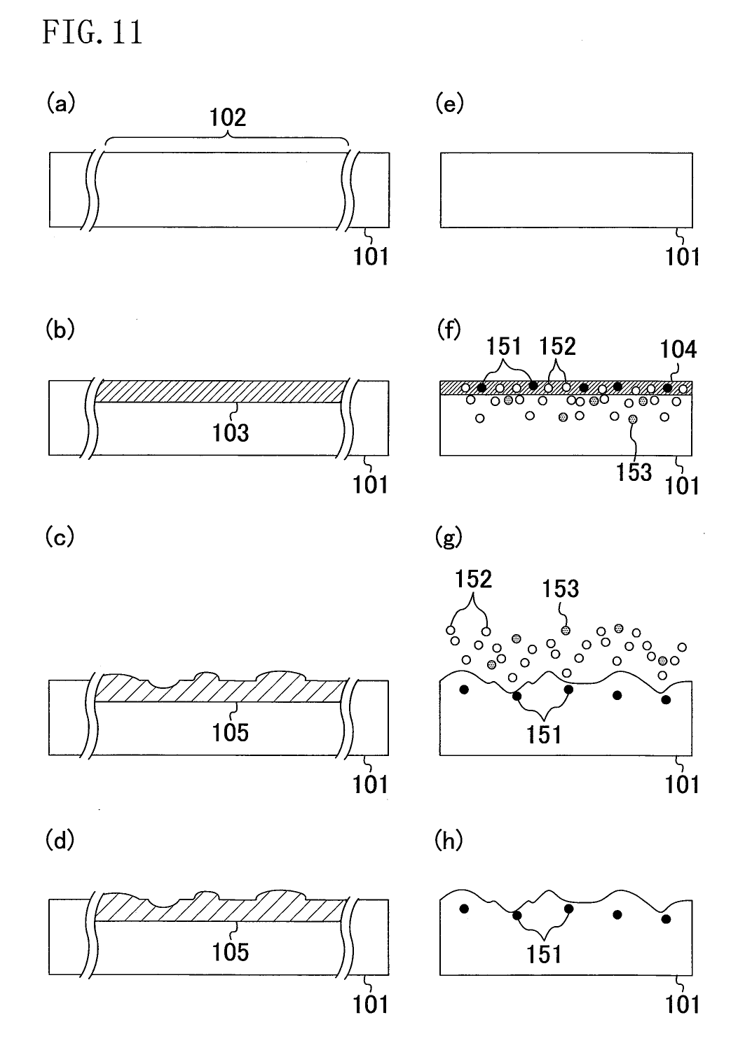

FIGS. 11(a)-11(d) are cross-sectional views showing steps of a method for manufacturing a semiconductor device according to the first comparative example, specifically, a method in which plasma doping is performed using B₂H₆ diluted with He as the material gas, after which millisecond-order rapid heating is performed by LSA, followed by the activation of the impurity using spike RTA, and FIGS. 11(e)-11(h) show, on an enlarged scale, a portion of an extension formation region (including a source/drain formation region) shown in FIGS. 11(a)-11(d) up to a depth of 100 nm from the substrate surface.

First, as shown in FIGS. 11(a) and 11(e), there is provided a support substrate 101 having a thickness of 800 μm and being in a silicon crystal state, for example. Then, an isolation trench (not shown) is formed by patterning in the support substrate 101, thereby forming an active region 102 where a source/drain region and an extension region of an N-type MISFET are formed.

Then, as shown in FIGS. 11(b) and 11(f), plasma doping is performed using B₂H₆ diluted with He on an extension formation region in the support substrate 101, thereby doping the region with boron which is a p-type impurity, thus forming an impurity implantation layer 103. In this process, at the same time as the boron 151 which is an impurity is implanted into the support substrate 101, the hydrogen 152 and the helium 153 which are diluents are also implanted into the support substrate 101. At the same time with the impurity implantation, an amorphous layer 104 is formed on the surface of the support substrate 101.

Then, as shown in FIGS. 11(c) and 11(g), millisecond-order rapid heating operation such as LSA is performed on the impurity implantation layer 103 to thereby electrically activate the impurity (the boron 151) of the impurity implantation layer 103, thus forming an impurity diffusion layer 105 to be an extension region, for example. In this process, the following problem occurs because the diffusion coefficients of hydrogen and helium which are diluents in plasma doping are an order or orders of magnitude larger than those of impurities forming the impurity region such as boron, arsenic and phosphorus. That is, when millisecond-order rapid heating such as laser heating is performed on the impurity implantation layer 103 in which the hydrogen 152 and the helium 153 have been implanted together with the boron 151, the hydrogen 152 and the helium 153 having large diffusion coefficients are rapidly eliminated from the silicon substrate 101 while boron is electrically activated. Thus, as shown in FIGS. 11(c) and 11(g), irregularities are formed on the surface of the silicon substrate 101.

Then, a heating operation using spike RTA is performed on the impurity diffusion layer 105 as shown in FIGS. 11(d) and 11(h) in order to electrically activate those atoms of the boron 151 that are remaining electrically inactive even after millisecond-order heating by LSA. Since helium and hydrogen have already been eliminated from the silicon substrate 101, irregularities are not newly formed on the surface of the silicon substrate 101 by spike RTA.

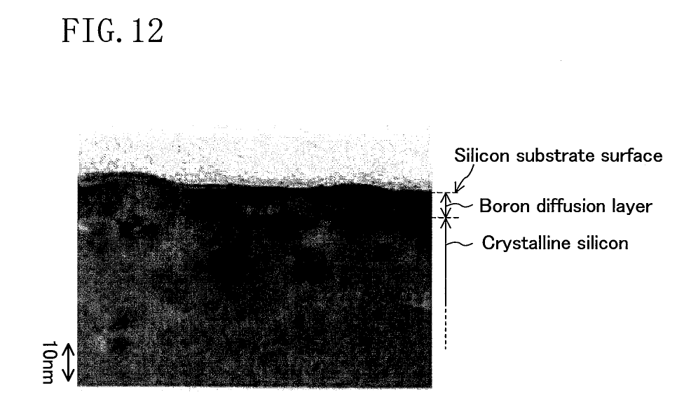

FIG. 12 is a cross-sectional TEM image of a silicon substrate surface portion obtained when an impurity is electrically activated by laser heating without performing preliminary heating following plasma doping in the first comparative example. As shown in FIG. 12, irregularities are generated on the silicon substrate surface after the laser heating in the first comparative example. This is because hydrogen and helium rapidly diffuse to the outside of the silicon substrate.

As described above, if, in the first comparative example, a method disclosed in Non-Patent Document 2 in which the impurity is electrically activated using spike RTA after millisecond-order heating by LSA is applied to a silicon substrate into which an impurity has been introduced using plasma doping, irregularities are generated on the silicon substrate surface because the diluent rapidly diffuses to the outside of the substrate. That is, where the impurity is electrically activated by laser heating without performing preliminary heating after the plasma doping, it is possible, to some extent, to form a shallow impurity region to be an extension region and to reduce the sheet resistance of the impurity region, but irregularities are generated on the substrate surface and intended semiconductor device characteristics cannot be obtained, thus failing to realize effects of the present invention.

Now, a problem occurring with a device having a substrate surface with irregularities thereon will be described.

Device miniaturization, which decreases the electron traveling distance and decreases the charging/discharging capacity, is necessary not only for increasing the degree of integration, but also for realizing a high-speed operation of the circuit. Therefore, device miniaturization is pursued as long as it is permitted technique-wise and cost-wise. Now, since a MOSFET (metal-oxide-semiconductor field-effect transistor) formed on a silicon substrate is currently used as a transistor in most large-scale LSIs, the problem will be described while focusing on the miniaturization of a MOSFET.

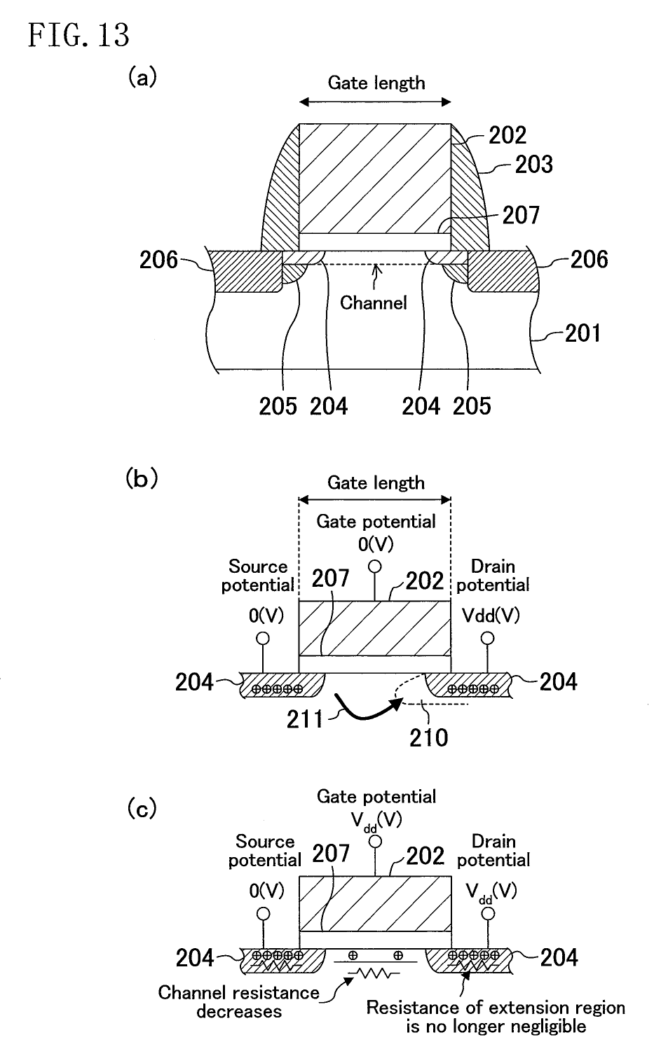

FIG. 13(a) shows an example of a cross-sectional structure of a MOSFET. As shown in FIG. 13(a), a gate electrode 202 is formed on a silicon substrate 201 with a gate insulating film 207 interposed therebetween. An insulative sidewall spacer 203 is formed on the side surface of the gate electrode 202. An extension region 204 is formed in a portion of the silicon substrate 201 that is located under the side surface of the gate electrode 202, and a punch-through stopper 205 is further formed under the extension region 204. A source/drain region 206 is formed in portions of the silicon substrate 201 that are located on opposite sides of the gate electrode 202 so that the source/drain region 206 is adjacent to the extension region 204 and the punch-through stopper 205.

In the MOSFET shown in FIG. 13(a), the potential on the surface of the silicon substrate 201 in a portion directly under the gate electrode 202 is changed by the gate voltage, thereby turning ON/OFF a carrier flow (an electron flow with an N-type MOSFET, and a positive hole flow with a P-type MOSFET) flowing from one (the source region) of the source/drain regions 206 to the other (the drain region) via the substrate surface portion (i.e., the channel) where the potential is changed. Herein, it is ideal that the electric resistance of the channel is as close to 0 as possible when it is ON, and the carrier flow is completely blocked when it is OFF.

FIGS. 13(b) and 13(c) are cross-sectional views schematically showing the OFF state and the ON state, respectively, of a MOSFET with a shortened gate length. In FIGS. 13(b) and 13(c), like elements to those of the MOSFET shown in FIG. 13(a) are denoted by like reference numerals and will not be further described below.

As shown in FIG. 13(b), as the gate length is shortened in an OFF state, the extension region 204 on the source side comes into contact with a space charge region 210 in the vicinity of the extension region 204 on the drain side, i.e., a region where the potential is increased by being influenced by the drain voltage. At this point, the potential of a deep portion of the substrate away from the gate electrode 202 remains high by being influenced by the drain voltage even if the gate voltage is lowered. Therefore, even if the gate voltage is set to 0 V in an attempt to turn OFF the MOSFET, a leak current 211 flows through a high-potential portion of the substrate. This is a phenomenon called the “short channel effect”, and is a phenomenon that has always been a problem in miniaturizing a MOSFET. For miniaturizing a MOSFET while suppressing the short channel effect, miniaturization has been done basically in accordance with the scaling method. In the scaling method, in addition to simply shrinking a planar-direction dimension such as the gate length, the dimension in the depth direction is also shrunk in the same proportion, thereby cutting off the leak current flowing through a deep portion of the substrate and preventing the short channel effect.

On the other hand, as shown in FIG. 13(c), if the gate length is shortened in an ON state, there is a desirable effect that the channel resistance is reduced, but when the resistance of the extension region 204 is increased, the effect obtained by shortening the gate length is nullified. Thus, it is necessary to reduce the resistance of the extension region 204 together with the shortening of the channel.

In summary, a condition for success in miniaturization of a MOSFET is to suppress the short channel effect in an OFF state and to reduce the resistance in an ON state. In order to solve this, there is needed a technique for forming an extension region with a small thickness and a small resistance.

However, the following device problem occurs when an impurity such as boron, arsenic or phosphorus is introduced into a substrate using plasma doping and then the implanted impurity is electrically activated by laser heating in order to form an extension region with a small thickness and a small resistance. That is, it is presumed that the position where irregularities are generated on the substrate surface (strictly, the position where the recess is formed) in the step of activating the implanted impurity by laser heating is determined by the combination of variations across the substrate surface in the amount of hydrogen or helium introduced into the substrate by the plasma doping and variations across the substrate surface in the laser irradiation output power. That is, it is believed that a recess is formed where the position at which the implantation dose of hydrogen or helium is relatively large coincides with the position at which the laser output power is relatively high.

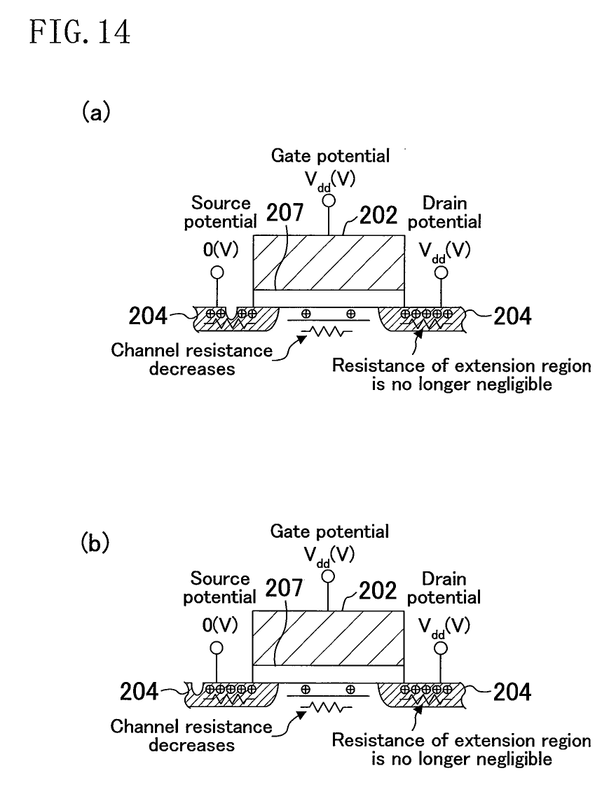

FIG. 14(a) is a cross-sectional view schematically showing the ON state of a MOSFET in which there is a recess near the gate electrode, and FIG. 14(b) is a cross-sectional view schematically showing the ON state of a MOSFET in which there is a recess at a position away from the gate electrode. In FIGS. 14(a) and 14(b), like elements to those of the MOSFET shown in FIG. 13(a) are denoted by like reference numerals and will not be further described below.

As shown in FIG. 14(a), if a recess is formed in a portion of the extension region 204 located near the gate electrode 202, it becomes very difficult for the current to flow because the recess is formed in a portion of the extension region 204 where the current path is narrowest in an ON state of the MOSFET. That is, the electric resistance between the source region and the drain region becomes very high.

On the other hand, as shown in FIG. 14(b), if a recess is formed in a portion of the extension region 204 located away from the gate electrode 202, the degree by which the current flow is blocked is small, as compared with a case where a recess is formed near the gate electrode 202, because the recess is formed in a portion of the extension region 204 where the current path is relatively wide in an ON state of the MOSFET. That is, in such a case, the degree by which the electric resistance between the source region and the drain region is increased is small as compared with a case where a recess is formed near the gate electrode 202.

Now, the position at which a recess is formed cannot be controlled as is obvious from the mechanism of formation thereof, and where in the laser-irradiated region it is formed cannot be known. Therefore, depending on the position where a recess is formed in each MOSFET, the electric resistance between the source region and the drain region varies significantly, thus resulting in variations in the transistor performance.

As described above, the formation of irregularities on the substrate surface can be a significant problem in obtaining intended semiconductor device characteristics.

### Second Comparative Example

A second comparative example is directed to a method for manufacturing a semiconductor device disclosed in Sungkweon Beak, et al., Characteristics of Low-Temperature Preannealing Effects on Laser-Annealed P+/N and N+/P Ultra-Shallow Junctions, Extended Abstracts of the Fourth International Workshop on Junction Technology, p. 54-57, 2004, specifically, a method in which an impurity is implanted into a silicon substrate using plasma doping, followed by a heating operation (e.g., RTA) such that crystalline recovery occurs in the amorphous layer, after which the impurity is electrically activated by millisecond-order laser heating. In the second comparative example, during a heating operation performed before laser heating, crystalline recovery occurs in the amorphous layer formed by plasma doping, thereby lowering the efficiency in activating the impurity by laser heating such as LSA, for example.

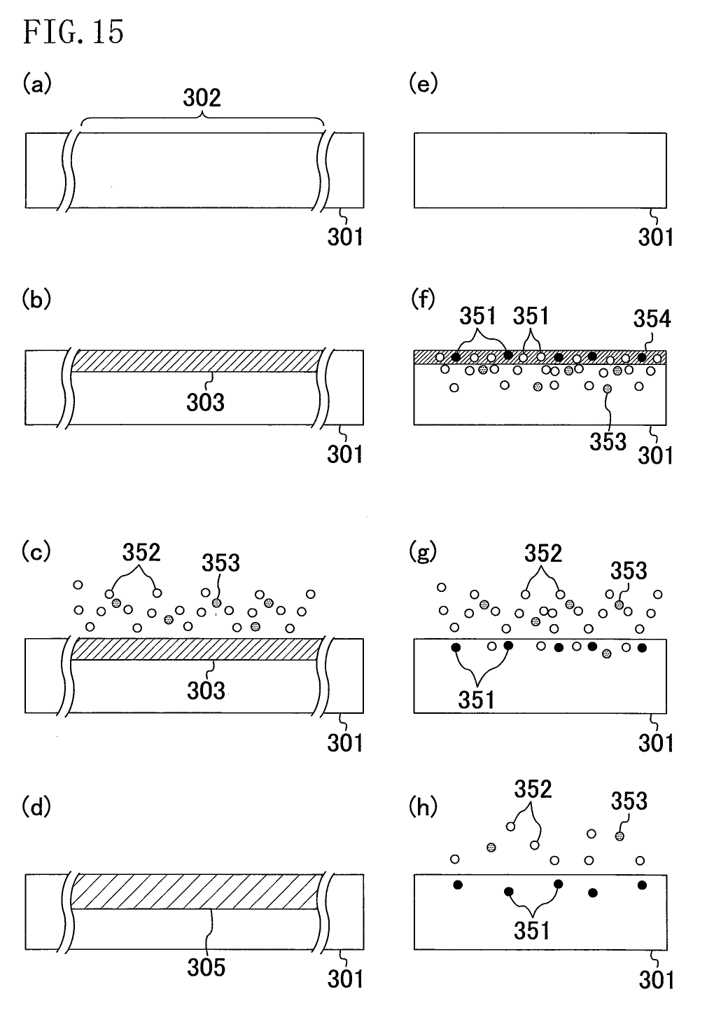

FIGS. 15(a)-15(d) are cross-sectional views showing steps of a method for manufacturing a semiconductor device according to the second comparative example, and FIGS. 15(e)-15(h) show, on an enlarged scale, a portion of an extension formation region (including a source/drain formation region) shown in FIGS. 15(a)-15(d) up to a depth of 100 nm from the substrate surface.

First, as shown in FIGS. 15(a) and 15(e), there is provided a support substrate 301 having a thickness of 800 μm and being in a silicon crystal state, for example. Then, an isolation trench (not shown) is formed by patterning in the support substrate 301, thereby forming an active region 302 where a source/drain region and an extension region of an N-type MISFET are formed.

Then, as shown in FIGS. 15(b) and 15(f), plasma doping is performed using B₂H₆ diluted with He on an extension formation region in the support substrate 301, thereby doping the region with boron which is a p-type impurity, thus forming an impurity implantation layer 303. In this process, at the same time as boron 351 which is an impurity is implanted into the support substrate 301, hydrogen 352 and helium 353 which are diluents are also implanted into the support substrate 301. At the same time with the impurity implantation, an amorphous layer 304 is formed on the surface of the support substrate 301.

Then, as shown in FIGS. 15(c) and 15(g), a heating operation for 5 minutes at 300° C. is performed on the support substrate 301 so that the amorphous layer 304 disappears as crystalline recovery occurs in the amorphous layer 304. In this process, the boron 351 which is an impurity has a low diffusion coefficient and thus does not diffuse substantially, whereas the hydrogen 352 and the helium 353 which are diluents have high diffusion coefficients and thus diffuse slowly to the outside of the support substrate 301.

Then, as shown in FIGS. 15(d) and 15(i), laser heating, e.g., millisecond-order rapid heating operation such as LSA, is performed on the impurity implantation layer 303 to thereby electrically activate the impurity (the boron 351) of the impurity implantation layer 303, thus forming an impurity diffusion layer 305 to be an extension region, for example. At this point, the amounts of the hydrogen 352 and the helium 353 which are diluents are already small in the support substrate 301, and therefore irregularities are not formed on the substrate surface. Note however that the amorphous layer 304 has disappeared due to crystalline recovery occurring in the amorphous layer 304 by a heating operation shown in FIGS. 15(c) and 15(g).

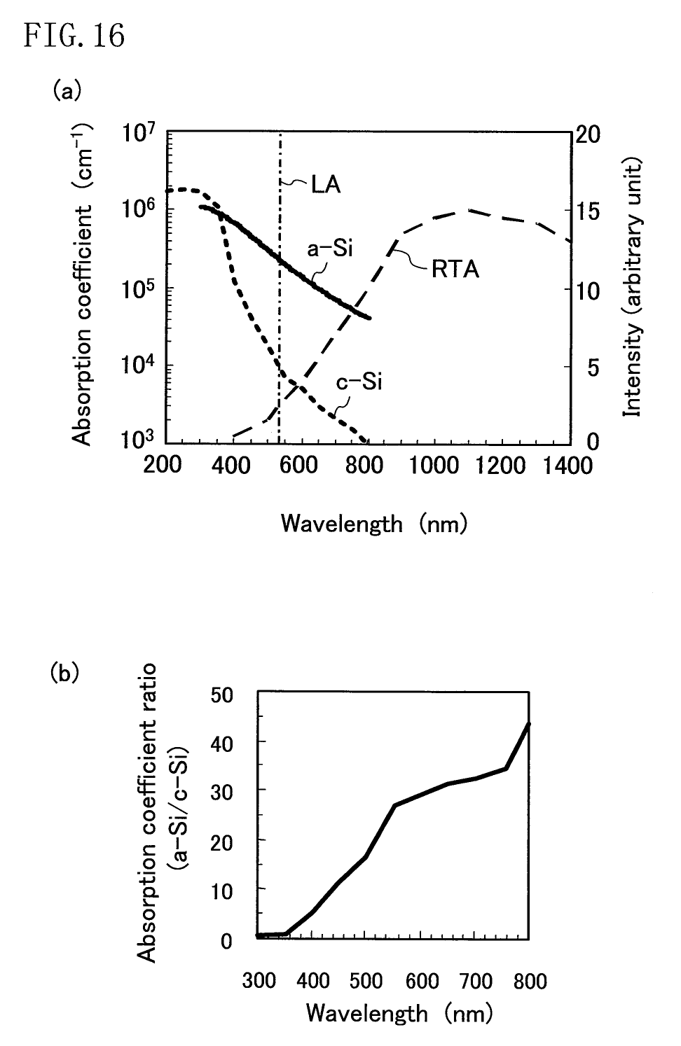

FIG. 16(a) shows the optical absorption coefficients of amorphous silicon crystal (a-Si) and crystalline silicon (c-Si) with respect to the wavelength of light, and FIG. 16(b) shows the ratio of the optical absorption coefficient of a-Si with respect to that of c-Si. Herein, FIG. 16(a) shows the intensity of laser heating (LA) and that of RTA with respect to the wavelength of light. As shown in FIGS. 16(a) and 16(b), a comparison between the optical absorption coefficient of a-Si and that of c-Si around 535 nm which is the wavelength of light of LA shows that the optical absorption coefficient of a-Si is about 20 times or more that of c-Si.

That is, if crystalline recovery occurs in the amorphous layer 304 formed on the impurity implantation layer 303 before laser heating as in the second comparative example, the heating efficiency in the laser heating decreases, thus detracting from the efficiency in electrically activating the impurity. As a result, in the second comparative example, the sheet resistance value of the impurity diffusion layer 305 to be an extension region, or the like, will be higher than the present invention or the first comparative example. Therefore, it is not possible to realize effects of the present invention by the second comparative example.

### INDUSTRIAL APPLICABILITY

The present invention relates to a semiconductor device and a method for manufacturing the same. Particularly, the present invention is very useful in realizing intended characteristics of a semiconductor device obtained by implanting an impurity by plasma doping and electrically activating the impurity by laser heating.

1-13. (canceled)

14. A method for manufacturing a semiconductor device comprising:
a plasma doping step of exposing a semiconductor to a plasma generated from a mixed gas of an impurity and a diluent so as to implant the impurity into the semiconductor;
a preliminary heating step, after the plasma doping step and before the laser heating step, of heating the semiconductor so that a dose of the diluent in the semiconductor is smaller than that of the impurity by utilizing a difference between a thermal diffusion coefficient of the impurity in the semiconductor and that of the diluent; and
a laser heating step of electrically activating the impurity implanted into the semiconductor using a laser, wherein
the plasma doping step includes a step of forming an amorphous layer on a surface of the semiconductor, and
the preliminary heating step is performed with a temperature and a time such that the amorphous layer remains.

15. The method for manufacturing a semiconductor device of claim 14, wherein
the preliminary heating step is performed with a temperature and a time such that the impurity does not substantially diffuse in the semiconductor.

16. The method for manufacturing a semiconductor device of claim 14, wherein
the semiconductor is silicon, and
the preliminary heating step is performed at a temperature of 50° C. or more and 300° C. or less.

17. The method for manufacturing a semiconductor device of claim 14, wherein
the method further comprises another heating step of heating the semiconductor after the laser heating step.

18. The method for manufacturing a semiconductor device of claim 17, wherein
the other heating step is performed using spike RTA.

19. The method for manufacturing a semiconductor device of claim 17, wherein
the other heating step includes a step of heating the semiconductor at a temperature of 800° C. or more for 30 seconds or less.

20. The method for manufacturing a semiconductor device of claim 14, wherein
the laser heating step is performed using LSA.

21. The method for manufacturing a semiconductor device of claim 14, wherein
the laser heating step includes a step of heating the semiconductor at a temperature of 900° C. or more for 10 milliseconds or less.

22. The method for manufacturing a semiconductor device of claim 14, wherein
the impurity is boron, arsenic or phosphorus.

23. The method for manufacturing a semiconductor device of claim 14, wherein
the diluent is hydrogen.

24. The method for manufacturing a semiconductor device of claim 14, wherein
the diluent is a rare gas.

25. The method for manufacturing a semiconductor device of claim 24, wherein
the diluent is helium.
